(19) United States
(12) Patent Application Publication
(10) Pub. No.: US 2002/0072216 A1
(43) Pub. Date: Jun. 13, 2002

(54) Manufacturing method for multilayer high density substrate

(76) Inventors: Wen Lo Shieh, Kaohsiung City (TW); Fu Yu Huang, Kaohsiung City (TW); Feng Chang Tu, Kaohsiung City (TW); Hui Pin Chen, Kaohsiung City (TW); Ning Huang, Kaohsiung City (TW); Hsuan Jui Chang, Kaohsiung City (TW); Chia-Chieh Hu, Kaohsiung City (TW); Chung Ming Chang, Kaohsiung City (TW); Hua-Wen Chiang, Kaohsiung City (TW); Yung-Cheng Chuang, Kaohsiung City (TW)

Correspondence Address: Wen Lo Shieh, PO Box 82-144, Taipei, TW

(21) Appl. No.: 09/833,697

(22) Filed: Apr. 13, 2001

(30) Foreign Application Priority Data
Nov. 27, 2000 (TW) 089125424

(51) Int. Cl. H01L 21/44

(52) U.S. Cl. 438/614

(57) ABSTRACT

The present invention relates to a manufacturing method for multilayer high density substrate. The circuit layout of the first layer substrate of the multilayer board requires a high demand of pitch density, and therefore polyimide layer is used to make into polyimide substrate (or other high density polymeric film substrate), and combines with the non-high density multilayer board formed from second layer board (or more layer boards) made of organic substrate. In making the organic multilayer board, the adjacent surface of the first layer polyimide substrate (or high density polymeric film substrate), corresponding to appropriate solder pad position of the first layer polyimide substrate (or high density polymeric film substrate), is formed with a solder bump. Thus, when the individual layer board and the first layer substrate are combined, direct heating and compression are applied, such that the bump and the solder pad are bound and electrically connected.

### BACKGROUND OF THE INVENTION

(a) Technical Field of the Invention

The present invention relates generally to a manufacturing method for multilayer high density substrate, and in particular, a method employing polyimide (PI) layer (or other high density, polymeric film material) to form polyimide substrate (or high density polymeric film substrate) to form a first layer of the multilayer boards.

(b) Description of the Prior Art

Electronic products have developed at a rapid pace towards high speed, high function, high frequency, high density, digital, lightweight and being environmentally friendly. In view of the substrate 1′ or multilayer substrate to fan out the connection pin 11′ by the circuit 12′, as shown in FIG. 1, it is a challenge in view of the fine wires on the substrate or the circuit board.

Referring to FIG. 2, there is shown a conventional high density multilayer board, wherein the two sides of the core substrate are provided with a plurality of layers of conduction layer and insulation layer so that the high density connection pins are sufficiently fanned out by means of the conduction layer of the various layer boards. The manufacturing of the high density multilayer board normally makes use of polyimide layer to form a substrate, or employs organic material to form a substrate. The organic substrate of the high density multilayer board 2′ made from organic material is where the core substrate 211′ is formed into conduction layer 212′ and epoxy resin insulation layer 213′ with a plurality of conduction patterns by means of a build up method. By continuous accumulation, a multilayer conduction circuit is formed, and the top layer surface and the bottom face of the bottom layer are provided with solder pad or solder ball 215′ so as to connect with another chip 3′ or substrate (not shown). However, the circuit density of the organic substrate is restricted by the characteristic of the material and it cannot be of the same high density as that of a polyimide substrate. However, if a polyimide layer is used to be the substrate material for other layers, a high density wire substrate of fine pitch can be formed. The polyimide raw material is very expensive and if all the layers are made from polyimide substrate, then the entire polyimide multilayer board will be very expensive (as shown in FIG. 2).

### SUMMARY OF THE INVENTION

Accordingly, it is an object of the present invention to provide a manufacturing method for multilayer high density substrate, wherein a novel composition is employed and the steps of compression are simple such that the cost of production is low.

Yet another object of the present invention is to provide a manufacturing method for multilayer high density substrate, wherein polyimide substrate is employed to be the first layer board of the multilayer boards, and a non-high density organic substrate is employed to form the second and subsequent layer boards.

A further object of the present invention is to provide a manufacturing method for multilayer high density substrate, wherein the bonding between the surface layer of the second layer board and the soldered pad at the bottom section of the first layer polyimide substrate is by the method of solder bump bonding, and the I/O connection point of the second layer boards is a solder bump which is combined by compression with the first polyimide substrate. This will improve and simplify the manufacturing process.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts. Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a top schematic view of a conventional high density multilayer board.

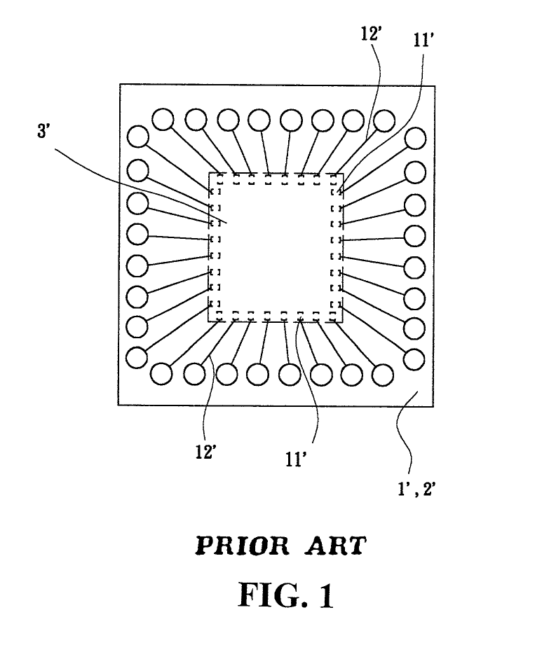

FIG. 2 is a structure of a conventional high density multilayer board.

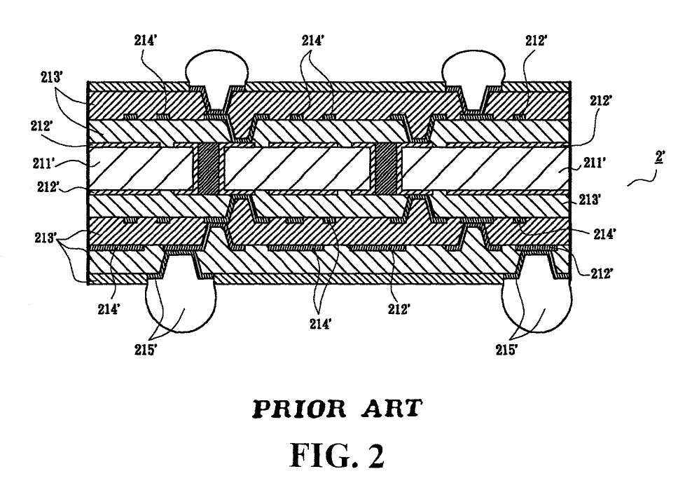

FIGS. 3a- 3b show the manufacturing method of the multilayer high density substrate of the present invention.

FIGS. 4a- 4b show another preferred embodiment of the present invention.

### DETAILED DESCRIPTION OF THE PREFERRED EMBODIMENT

For the purpose of promoting an understanding of the principles of the invention, reference will now be made to the embodiment illustrated in the drawings. Specific language will be used to describe same. It will, nevertheless, be understood that no limitation of the scope of the invention is thereby intended, such alterations and further modifications in the illustrated device, and such further applications of the principles of the invention as illustrated herein being contemplated as would normally occur to one skilled in the art to which the invention relates.

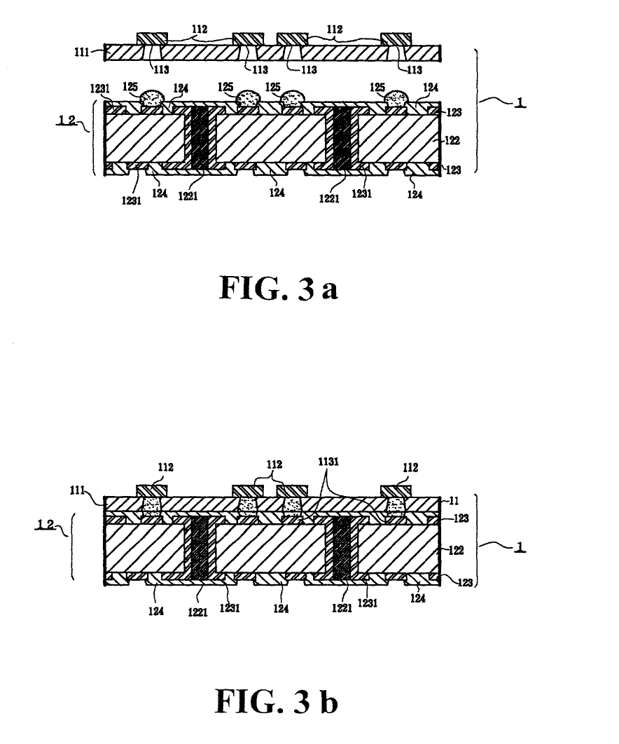

Referring to FIGS. 3a to 3b, there is shown a manufacturing method for multilayer high density substrate employing polyimide substrate to form the first layer (or other high density, polymeric film material) to combine with a non-high density organic substrate as the second layer board formed from organic material, comprising the steps of:

(a) forming a first layer polyimide substrate 11 (or high density polymeric film substrate) of the multilayer board 1 by employing polyimide (or other high density polymeric film) 111, on the polyimide substrate 11 (or high density polymeric film substrate) forming narrow pitch circuit layout 112 by means of circuit formation method (such as electroplating method and the prefabricated circuit 112 being directed to the bottom face of the polyimide substrate 11, the circuit density being appropriately extended and diluted, and the bottom face being provided with a solder pad 113 at an appropriate position;

(b) forming a second layer non-high density organic substrate using organic material 12, and the two sides of a core substrate 122 being mounted with conduction layer 123 to arrange a circuit 1231 and insulation layer 124 and the top face of the circuit 1231 layout and the bottom face of the top layer polyimide substrate 11 (or high density polymeric layer film substrate) being soldered with a solder bump 125 at a corresponding position to the pad solder 113, the circuit 123 employing a path 1221 to pass through the core substrate 122 to the conduction layer 123 at the bottom face of the non-high density organic substrate 12, distributing the circuit 1231 and lower the circuit density; and

(c) heating and compressing the first layer polyimide substrate 11 (or high density polymeric film substrate) and the second layer, non-high density organic substrate 12 after alignment, and the solder bump 124 of the surface of the second layer non-high density organic substrate 12 and the bottom face of the first polyimide substrate 11 (or high density polymeric film substrate) being soldered together to be electrically connected.

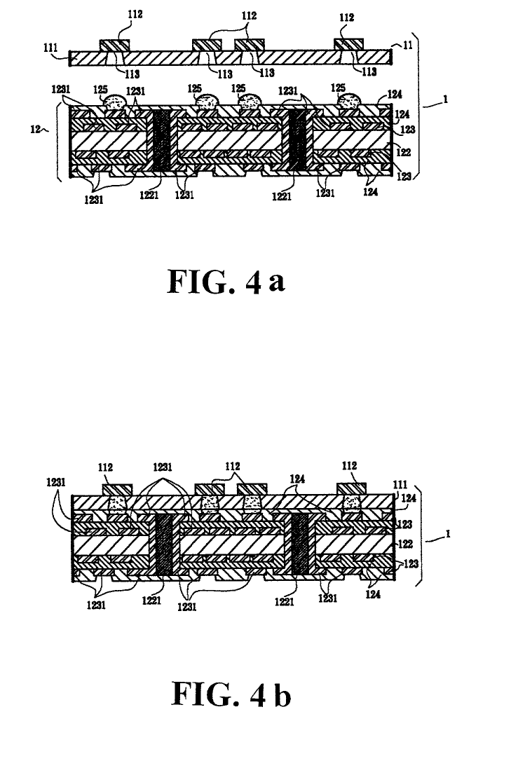

As shown in FIGS. 4a- 4b, the core substrate, the conduction layer, the insulation layer are bounded together in sequence to repeatedly form into further or more multilayer and to lower the circuit density of the first layer.

In accordance with the present invention, the first layer of the multilayer by means of the polyimide substrate (or high density polymeric film substrate) can provide very fine pitch circuit layout, and non-high density organic material is used as other subsequent layer boards which do not need the same circuit density as that of the first layer. In accordance with the present method, a circuit pitch layout which complies with requirements can be manufactured so as to lower the cost of material. Furthermore, the compression and combination of the first layer board and the second layer board do not require to be further soldered, but has direct compression with heating. After the boards are compressed and combined, a fine pitch, low cost high density interior connected substrate is obtained.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

We claim:

1. A manufacturing method for multilayer high density substrate employing polyimide substrate of the first layer (or high density polymeric film substrate) to combine with non-high density organic substrate in the second layer board, comprising the steps of:
(a) forming a first layer polyimide substrate (or high density polymeric film substrate) by employing polyimide (or other high density polymeric film), on the polyimide substrate (or high density polymeric film substrate) forming narrow pitch circuit layout by means of circuit formation method and the prefabricated circuit being directed to the bottom face of the polyimide substrate, the circuit density being appropriately extended and diluted, and the bottom face being provided with a solder pad at an appropriate position;
(b) forming a second layer non-high density organic substrate using organic material, and the two sides of a core substrate being mounted with conductor layer to arrange circuit and insulation layer and the top face of the circuit layout and the bottom face of the top layer polyimide substrate (or high density polymeric layer film substrate) being soldered with a solder bump at a corresponding position, the circuit employing a path to pass through the core substrate to the conduction layer at the bottom face of non-high density organic substrate, distributing the circuit and lower the circuit density; and
(c) heating and compressing the first layer polyimide substrate (or high density polymeric film substrate) and the second layer, non-high density organic substrate after alignment, and the solder bump of the surface of the second layer non-high density organic substrate and the bottom face of the first polyimide substrate (or high density polymeric film substrate) being soldered together to be electrically connected.

2. A manufacturing method as set forth in claim 1, wherein the second layer non-high density organic substrate comprises the core substrate, the conduction layer, the insulation layer in sequence to repeatedly form into further multilayer and to lower the circuit density of the first layer.
